(19) United States
(12) Patent Application Publication
(10) Pub. No.: US 2023/0260946 A1
(43) Pub. Date: Aug. 17, 2023

(54) AG PASTE COMPOSITION AND BONDING FILM PRODUCED USING SAME

(71) Applicant: AMOGREENTECH CO., LTD., Gimpo-si, Gyeonggi-do (KR)

(72) Inventors: Younghwan JUN, Gimpo-si (KR); Sangjin OH, Gimpo-si (KR); Yongsul SONG, Gimpo-si (KR)

(73) Assignee: AMOGREENTECH CO., LTD., Gimpo-si, Gyeonggi-do (KR)

(21) Appl. No.: 18/009,691

(22) PCT Filed: Jun. 8, 2021
(86) PCT No.: PCT/KR2021/007119

§ 371 Date: Dec. 9, 2022

(30) Foreign Application Priority Data
Jun. 11, 2020 (KR) 10-2020-0070817

(51) Int. Cl. H01L 23/00; H01B 1/22; B22F 1/10; B22F 1/054

(52) U.S. Cl. CPC H01L 24/29; H01L 24/32; H01B 1/22; B22F 1/10; B22F 1/0551; H01L 2224/29339; H01L 2224/29499; H01L 24/83; H01L 2224/8384; H01L 2924/20106; H01L 2924/20107; H01L 2924/20108; H01L 2224/32225; B22F 2301/255; B22F 2304/054; B22F 2304/056

(57) ABSTRACT

The present disclosure relates to an Ag paste composition and a bonding film produced using same, the Ag paste composition being coated on a first object, and the first object being pressure sintered toward a second object side, thereby forming a sintered bonding layer between the first object and the second object, wherein the Ag paste composition comprises 90˜99 wt % of Ag powder, and 1˜10 wt % of an organic binder. The present disclosure controls the specific surface area and grain shape of the Ag powder, even without applying a spherical nanoparticle powder, and thus has the advantages of lowering a bond temperature and increasing bond density, thereby enabling the improvement of bond strength and reliability.

### TECHNICAL FIELD

The present disclosure relates to an Ag paste composition and a bonding film manufactured using the same, and relates to an Ag paste composition used for bonding a semiconductor chip and a substrate and a bonding film manufactured using the same.

### BACKGROUND ART

A semiconductor chip is electrically connected to other external elements through a substrate, and a wire bonding technology is used to provide this connection path. However, the wire bonding technology has reached its limit as the need for ultra-high-speed and high-performance semiconductor chips increases, and a flip-chip or chip direct mounting technology has emerged as an alternative.

As the well-known flip chip technology, there is a method of soldering a semiconductor chip to a substrate using a solder paste.

Soldering bonding has an excellent processability as the semiconductor chip is bonded using solder paste when bonded to the substrate. However, the soldering bonding has a problem in that reliability is reduced when exposed to high temperature, thereby separating the bonded portion.

In addition, there is a reflow method of bonding the semiconductor chip to the substrate by printing a cream solder on the substrate when the semiconductor chip is bonded to the substrate, attaching parts thereon, and then melting the solder using a high-temperature heat source. The reflow method has an advantage of excellent bonding reliability. However, the reflow method has a problem in that voids are generated in the solder depending on conditions or the solder is lifted by the bending of the substrate, resulting in poor bonding.

In addition, there is a sintering method in which the semiconductor chip is bonded to the substrate using a silver (Ag) sintering paste when bonded to the substrate. The sintering method has an advantage of stably bonding the semiconductor chip to the board when exposed to high temperature as compared to the soldering method. However, the sintering method has problems in that it is difficult to uniformly apply the silver (Ag) sintering paste, a process is complicated, a process time is long, and expensive equipment is required.

### SUMMARY OF INVENTION

### Technical Problem

Therefore, the present disclosure is directed to providing an Ag paste composition and a bonding film manufactured using the same, which may stably bond a semiconductor chip to a substrate instead of a reflow method and a soldering method.

The present disclosure is directed to providing an Ag paste composition and a bonding film manufactured using the same, which can improve bonding stiffness and reliability by reducing a bonding temperature and increasing a bonding density, improve printability, prevent process defects due to shrinkage upon bonding sintering, and improve workability.

### Solution to Problem

According to features of the present disclosure for achieving the objects, an Ag paste composition according to the present disclosure is an Ag paste composition forming a sintered bonding layer between a first object and a second object by being coated on the first object and pressure-sintering the first object toward the second object and includes 90 to 99 wt % of Ag powder and 1 to 10 wt % of an organic binder.

The Ag powder may have an intermediate grain shape between a spherical nanoparticle shape and a flake form.

The Ag powder may have a specific surface area (Brunauer, Emmett, Teller (BET)) in the range of 1.3 to 1.8 m²/g.

The grain shape of the Ag powder may have a length of a long axis in the range of 0.80 μm to 1.3 μm and a thickness in the range of 0.04 μm to 0.08 μm.

The Ag paste composition may have a total content of an organic material is 2 wt % or less and a total content of the organic material of 0.1 wt % or less after pressure sintering.

The Ag paste composition may have a sintering temperature in the range of 200° C. to 300° C. upon pressure sintering.

A bonding film is a bonding film manufactured by using the Ag paste composition and includes a base film, a sticky layer formed on the base film, and a bonding layer formed on the sticky layer and made of the Ag paste composition.

The base film may be formed as one of a polyethylene (PET) film, a polyimide (PI) film, and a polyurethane (PU) film.

The sticky layer may be formed as an optical clear adhesive (OCA) or an optical clear resin (OCR).

The Ag paste composition may include 90 to 99 wt % of Ag powder and 1 to 10 wt % of an organic binder.

A sintered bonding layer may be formed between a first object and a second object by transferring the bonding layer made of the Ag paste composition to the first object and pressure-sintering the first object toward the second object, and a sintering temperature upon pressure sintering may be in the range of 200° C. to 300° C.

### Advantageous Effects of Invention

According to the present disclosure, it is possible to provide the Ag paste composition with improved bonding stiffness and reliability by manufacturing the Ag bulk to be the Ag powder having a clean particle surface, controlling the particle size of the Ag powder to reduce the bonding temperature without greatly increasing the surface area, and controlling the grain shape of the Ag powder to increase the bonding density.

The Ag paste composition can enable the low-temperature sintering even without applying the nano-particle spherical powder, prevent the occurrence of the excessive shrinkage on the bonded surface in the sintering process, and prevent process defects, thereby minimizing defects and securing the high bonding strength.

In addition, the Ag paste composition and the bonding film manufactured using the same according to the present disclosure can minimize the pores, thereby securing the high heat conductivity and reduce the sintering time, thereby increasing process efficiency when the parts such as the semiconductor chip and the spacer are bonded to the substrate by applying the pressure sintering method.

### BRIEF DESCRIPTION OF DRAWINGS

FIG. 1 is a cross-sectional view showing a state in which an Ag paste composition according to an embodiment of the present disclosure forms a bonding layer between a semiconductor chip and a substrate.

FIG. 2 is a cross-sectional view of the Ag paste composition according to the embodiment of the present disclosure manufactured to be a bonding film.

FIG. 3 is a flow chart showing a method of manufacturing the Ag paste composition according to the embodiment of the present disclosure.

FIG. 4 is a configuration diagram for describing an operation of synthesizing dry plasma powder according to an Example of the present disclosure.

FIG. 5 is a scanning electron microscope (SEM) photograph showing a particle size distribution of Ag powder after classification according to the Example of the present disclosure.

FIG. 6 is a configuration diagram for describing a bead milling process according to the Example of the present disclosure.

FIG. 7 is a SEM photograph showing a grain shape of the Ag powder subjected to the bead milling process according to the Example of the present disclosure.

FIG. 8 is a graph showing the result of the heat analysis of the Ag powder of FIG. 7.

FIG. 9 is a SEM photograph showing an example in which a specific surface area, grain shape, and shrinkage rate of the Ag powder were controlled through the classification and bead milling processes.

FIG. 10 is a graph comparing the bonding strength of the Ag paste composition according to the Example of the present disclosure with that of a competitor's product (Comparative Example).

FIG. 11 is a photograph of broken surfaces of the Example and Comparative Example in FIG. 10.

FIG. 12 is a photograph comparing shrinkage rates, the occurrence of bending, and micro-structures of a bonding layer of the Example of the present disclosure and a bonding layer of the Comparative Example (competitor's product).

FIG. 13 is a photograph comparing the shrinkage rates of the Example of the present disclosure and the Comparative Example.

FIG. 14 is a view for describing a state of being shrunk after sintering a bonding layer bonding an object to a substrate according to the embodiment of the present disclosure.

FIG. 15 is a photograph of a structure of a sintered bonding layer after arranging the Ag paste composition between a power semiconductor chip and a direct bonded copper (DBC) substrate and pressure-less sintering the same.

### DESCRIPTION OF REFERENCE NUMERALS

| | |
|---|---|
| 10: substrate | 11: ceramic base |
| 12, 13: metal layer | 20: semiconductor chip |
| 30: Ag paste composition | 30′: bonding layer after sintering |
| 30″: bonding layer before sintering | 40: bonding film |
| 41: base film | 41: sticky layer |

### DESCRIPTION OF EMBODIMENTS

Hereinafter, embodiments of the present disclosure will be described in detail with reference to the accompanying drawings.

An Ag paste composition according to the present disclosure is used for bonding a first object and a second object and forms a bonding layer between the first object and the second object. For example, the Ag paste composition is coated on the first object, and the first object is pressure-sintered toward the second object, and thus a sintered bonding layer is formed between the first object and the second object. An example in which the first object is a semiconductor chip, and the second object is a substrate will be described.

FIG. 1 is a cross-sectional view showing a state in which an Ag paste composition according to an embodiment of the present disclosure forms a bonding layer between a semiconductor chip and a substrate.

As shown in FIG. 1, an Ag paste composition 30 according to the present disclosure may be used for bonding a semiconductor chip 20 and a substrate 10. The Ag paste composition 30 bonds the semiconductor chip 20 to the substrate 10, and the Ag paste composition 30 uses Ag to improve the heat dissipation characteristics of the semiconductor chip.

The Ag paste composition 30 forms a bonding layer 30′ between the semiconductor chip 20 and the substrate 10. The semiconductor chip 20 may be an ultra-high-speed and high-performance semiconductor chip. Alternatively, the semiconductor chip 20 may be a power semiconductor chip, for example, a SiC or GaN semiconductor chip. The substrate 10 may be a ceramic substrate including a ceramic base 11 and metal layers 12 and 13 brazing-bonded to at least one surface of the ceramic base 11. For example, the substrate 10 may be one of an active metal brazing (AMB) substrate, a direct bonded copper (DBC) substrate, a thick printing copper (TPC) substrate, and a direct bonded aluminum (DBA) substrate.

As the substrate is switched from a current Si material base to SiC and GaN base having excellent performance, a driving temperature of the semiconductor chip rises to 300° C., and thus it is difficult to apply a soldering paste having a melting point of about 230° C. to bond the semiconductor chip and the substrate. Therefore, for the stable operation of the semiconductor chip 20, the Ag paste composition 30 having a high melting point is used for bonding the semiconductor chip 20 and the substrate 10.

The Ag paste composition 30 contains 90 to 99 wt % of Ag powder and 1 to 10 wt % of an organic binder. The organic binder includes an organic material and a solvent.

Ag has good heat dissipation characteristics due to a high heat conductivity and makes the bonding layer 30′ conductive.

The Ag paste composition 30 is manufactured to be Ag powder having a clean particle surface, and a particle size of the Ag powder is controlled to reduce a bonding temperature without greatly increasing a surface area. In addition, the Ag paste composition 30 controls a grain shape of the Ag powder to increase a bonding density, thereby improving a bonding strength and reliability.

When the semiconductor chip 20 is bonded to the substrate 10, a bonding process is completed in a short time mainly at 200° C. to 300° C. for stable bonding without breaking the semiconductor chip 20. However, since Ag requires a sintering temperature of about 800° C. in a bulk form, it is difficult to perform low-temperature sintering bonding. Therefore, the Ag paste composition 30 may have the maximum content of the Ag powder for sintering bonding at about 250° C. and form the Ag powder to be nanoparticle. The Ag paste composition 30 may have the maximum content of the Ag powder and the minimum content of the organic material in the range capable of uniform application, thereby reducing the bonding temperature. In addition, when the Ag paste composition 30 forms the Ag powder to be nanoparticle, the bonding temperature can be reduced.

However, when the Ag powder is formed to be nanoparticle, volatilization occurs quickly due to a high surface area of the nanoparticle in an actual mass production process, resulting in an increase in viscosity, thereby causing poor continuous printing workability. In addition, in order to solve this problem, when the content of the organic binder is increased in the Ag paste composition, the organic material is increased, resulting in a problem of sinterability. When the organic material increases, a sintering temperature increases.

In addition, when a large amount of the Ag powder formed of nanoparticle is used, the excessive shrinkage of a bonded surface occurs in the sintering process, and residual stress may be generated due to the shrinkage of the bonded surface between the semiconductor chip 20 and the substrate 10, thereby affecting reliability.

Therefore, instead of the method of reducing the bonding temperature using the high surface area of the nanoparticle, the Ag paste composition 30 according to the present disclosure increases the bonding density without greatly increasing the surface area of the Ag powder by controlling the particle surface of the Ag powder to be clean and controlling the particle size and grain shape (particle shape) of the Ag powder through classification and milling processes.

Since the surface area of the nanoparticle is not used to reduce the bonding temperature of the Ag paste composition, volatilization does not greatly occur in the mass production process, it is possible to improve continuous printing workability and prevent the excessive shrinkage of the bonded surface in the sintering process.

Since the Ag paste composition to which the Ag powder formed of nanoparticle is applied has a high specific surface area, the heat conductivity may be increased by increasing the content of the Ag powder to 98 to 99 wt %.

However, since the Ag paste composition according to the present disclosure may be manufactured to be about 90 wt % of a high-density Ag paste composition due to a lower specific surface area than a case in which the Ag powder formed of nanoparticle is applied.

When the Ag powder is smaller than 90 wt %, the heat conductivity is reduced due to the low content of Ag, and the organic material is increased due to a relative increase in the content of the organic binder, and thus the sintering temperature is increased. When the Ag powder exceeds 99 wt %, it is difficult to perform continuous printing work due to a relative reduction in the content of the organic binder.

The Ag powder has a specific surface area of 1.3 to 1.8 m²/g (Brunauer, Emmett, Teller (BET) particle diameter is in the range of 320 μm to 420 μm). In addition, the Ag powder has an intermediate grain shape between a spherical nanoparticle shape and a flake form. The intermediate grain shape between the spherical nanoparticle shape and the flake form solves the shrinkage rate problem of the spherical nanoparticle, improves the difficulty in the continuous printing work, and improves the lack of denseness when the flake form is sintered.

The Ag powder formed of the spherical nanoparticle has the advantage of high heat conductivity while having disadvantages in that in mass production, the occurrence of rapid volatilization caused by the high surface area of the nanoparticle makes the continuous printing work difficult and the high specific surface area causes the excessive shrinkage in the sintering process. The flake form has the advantage of having a lower shrinkage rate and better bonding force upon sintering than the Ag powder formed of the spherical nanoparticle while having the disadvantage in that the flake form has the lack of denseness as compared to the spherical nanoparticle upon sintering. Therefore, the Ag paste composition 30 according to the present disclosure uses the Ag powder having the intermediate grain shape between the spherical nanoparticle shape and the flake form, which compensate for the disadvantages of each of the spherical nanoparticle and the flake form.

The organic material allows Ag to have a high bonding force and to be applied uniformly.

The organic binder includes 1 to 10 wt %. When the organic binder is smaller than 1 wt %, it is difficult to perform the continuous printing work, and when the organic binder exceeds 10 wt %, the content of the organic material increases, and thus the sintering temperature (bonding temperature) increases. When the content of the organic material is reduced to 10 wt % or less, the thermal decomposition and bonding temperature of the Ag paste composition 30 may be reduced. The low bonding temperature enables the rapid sintering of the Ag paste composition 30. The rapid sintering of the Ag paste composition 30 reduces the shrinkage rate upon sintering and prevents the cracking of a sintered bonding layer 30″, thereby reducing a defect rate.

In the Ag paste composition 30, the grain shape of the Ag powder has a length of a long axis in the range of 0.8 μm to 1.3 μm and a thickness in the range of 40 nm to 80 nm.

The Ag paste composition 30 has a total content of the organic material of 0.5 wt % or less, and a total content of the organic material of smaller than 0.1 wt % after pressure sintering.

Alternatively, the Ag paste composition 30 has a total content of the organic material of 2 wt % or less, and a total content of the organic material of 0.1 wt % or less after pressure sintering. When the total content of the organic material of the Ag paste composition 30 is 2 wt % or less, the Ag paste composition may be applied to bond a thick film having a thickness of 200 μm or more.

The Ag paste composition 30 has a sintering temperature for bonding in the range of 200° C. to 300° C. The sintering temperature is a temperature at which the semiconductor chip 20 may be stably bonded to the substrate 10 without breakage.

The Ag paste composition 30 may be coated on a lower surface of the semiconductor chip 20 by an application or continuous printing method, and the semiconductor chip 20 coated with the Ag paste composition 30 may be heated and pressed toward the substrate 10 and bonded to the substrate 10.

Alternatively, the Ag paste composition 30 may be coated on the substrate 10 by the application or continuous printing method, and the semiconductor chip 20 may be heated and pressed toward the substrate 10 coated with the Ag paste composition 30 and bonded to the substrate 10.

Heating and pressing may be performed at 200° C. to 300° C., preferably, 250° C. for 2 to 5 minutes. The pressing may be performed in the range of 8 to 15 MPa. The pressing is to prevent the generation of voids. Upon pressure sintering, the bonding layer 30′ becomes dense without holes, and thus heat conductivity is increased and heat dissipation characteristics are excellent. In addition, the pressing enables rapid sintering.

The sintering temperature and time may be adjusted in the range described above in order to shorten a mass production time. For example, in the case of sintering, it is preferable to perform the pressing at 250° C. for 5 minutes, but the pressing may be performed at 300° C. for 2 minutes in order to improve mass productivity.

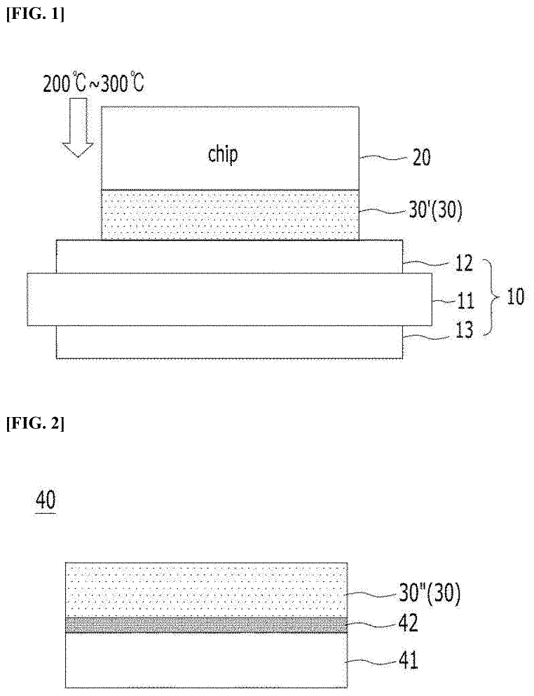

FIG. 2 is a cross-sectional view of the Ag paste composition according to the embodiment of the present disclosure manufactured to be a bonding film.

As shown in FIG. 2, the Ag paste composition 30 may be coated on an object to be bonded, but may be used by being manufactured to be the bonding film 40 and then transferred to the object to be bonded.

The bonding film 40 may include a base film 41, a sticky layer 42 formed on the base film 41, and the bonding layer 30″ formed on the sticky layer 42. The bonding layer 30″ may be formed by applying or printing the Ag paste composition 30 on the sticky layer 42 and drying the same. The printing may be screen printing or stencil printing. The sticky layer 42 improves the releasability of the bonding layer 30″ with respect to the base film 41.

As the base film 41, one of a polyethylene (PET) film, a polyimide (PI) film, and a polyurethane (PU) film may be used, and as the sticky layer 42, an optical clear adhesive (OCA) or an optical clear resin (OCR) may be used. Preferably, as the base film 41, the PET film is used, and as the sticky layer 42, the OCA film is used.

When the Ag paste composition 30 is manufactured in the form of a film, a height of the bonding layer 30″ may be significantly made uniform. When an object is bonded between two substrates, the height of the bonding layer 30″ needs to be uniform in order to prevent the occurrence of a tolerance between the two substrates and prevent the problem of a final product.

Moreover, by using the bonding film 40 when the object is bonded between the two substrates, it is possible to reduce defects such as voids and stand-offs as compared to the method of applying the Ag paste composition 30 to the object and bonding the object to the substrate. The voids are pores generated in the bonding layer after sintering, and the stand-off defect means that the object is tilted to any one side without being flatly bonded to the substrate. The object may be a semiconductor chip or a spacer for maintaining a separation distance between two substrates.

The base film 41 may have a thickness of 75 μm to 100 μm. A thickness of the bonding layer 30″ may be 40 μm to 200 μm, preferably, 50 μm. The bonding film 40 may enable the adjustment of the thickness and voids of the bonding layer 30″.

Meanwhile, the method of manufacturing the Ag paste composition described above includes an operation of preparing Ag powder and an operation of forming a composition by mixing 90 to 99 wt % of the manufactured Ag powder and 1 to 10 wt % of a binder.

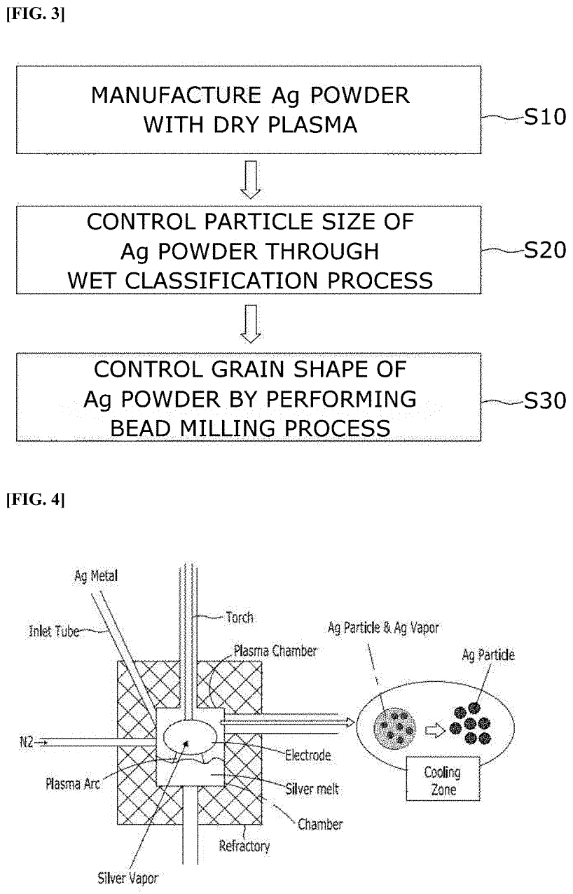

FIG. 3 is a flowchart for describing the method of manufacturing the Ag paste composition according to the embodiment of the present disclosure.

As shown in FIG. 3, the operation of manufacturing the Ag powder includes an operation S10 of manufacturing an Ag bulk to be the Ag powder by powder-synthesizing the Ag bulk by dry plasma, an operation S20 of controlling a particle size of the Ag powder through a wet classification process, and an operation S30 of controlling the grain shape of the Ag powder by performing a bead milling process.

The operation S10 of manufacturing the Ag bulk to be the Ag powder by powder-synthesizing the Ag bulk by dry plasma is an operation of dry plasma powder synthesis (PVD) and manufactures the Ag bulk to be the Ag powder having a clean particle surface.

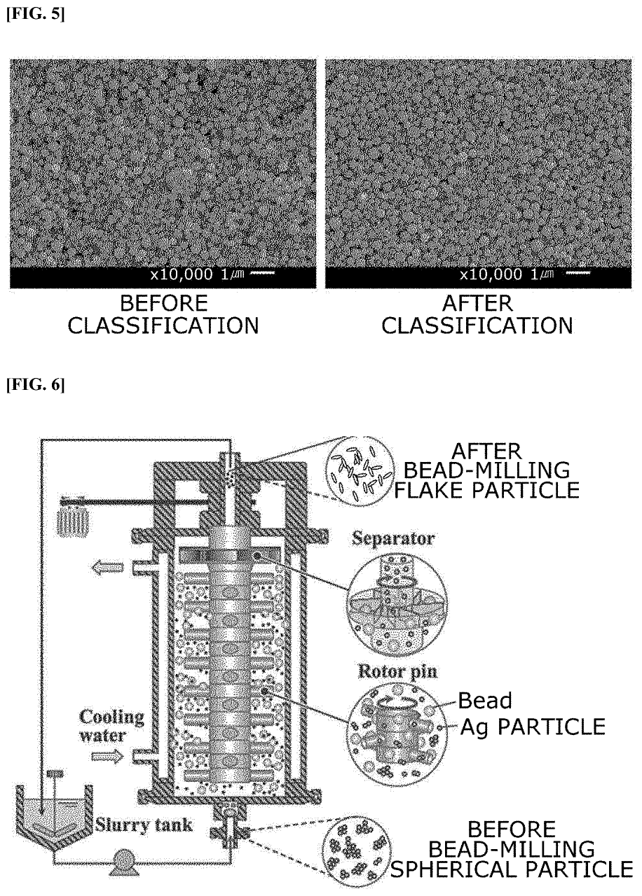

FIG. 4 is a configuration diagram for describing an operation of synthesizing dry plasma powder according to an Example of the present disclosure.

As shown in FIG. 4, in the operation S10 of manufacturing the Ag bulk to be the Ag powder by powder-synthesizing the Ag bulk by dry plasma powder, an N2 gas is sprayed into a chamber while the Ag bulk is injected into the chamber, and then power is applied to the chamber to convert the gas into plasma. In this process, the Ag powder containing the Ag gas is manufactured, and when the Ag powder is cooled, the Ag powder having the clean surface from which the Ag gas is removed is manufactured.

The particle size of the Ag powder having the clean surface is controlled through the wet classification process.

An operation S20 of controlling the particle size of the Ag powder through the wet classification process uses centrifugal separation (centrifugal classification). The centrifugal separation may control the particle size distribution of the particle.

FIG. 5 is a scanning electron microscope (SEM) photograph showing a particle size distribution of Ag powder after classification according to the Example of the present disclosure.

As shown in FIG. 5, the particle size distribution of the Ag powder after classification is uniformly controlled. The Ag powder after classification has a specific surface area of 1.3 to 1.8 m²/g (BET particle diameter is in the range of 320 μm to 420 μm). The Ag powder has a spherical particle.

After the operation S20 of controlling the particle size of the Ag powder through the wet classification process, the grain shape of the Ag powder is controlled by performing the bead milling process.

FIG. 6 is a configuration diagram for describing a bead milling process according to the Example of the present disclosure.

As shown in FIG. 6, the operation S30 of controlling the grain shape of the Ag powder by performing the bead milling process controls the grain shape of the Ag powder. When the Ag powder formed of the spherical particle is injected into a bead milling device, beads and the Ag powder are rotated together by the rotation of a rotational body, and the Ag powder is milled by the beads and becomes flat flake particles. The Ag powder is milled by the beads in a process of being injected into a lower portion of the bead milling device and moving to an upper portion thereof, and only the Ag powder may be discharged by a separator when exiting through an upper outlet.

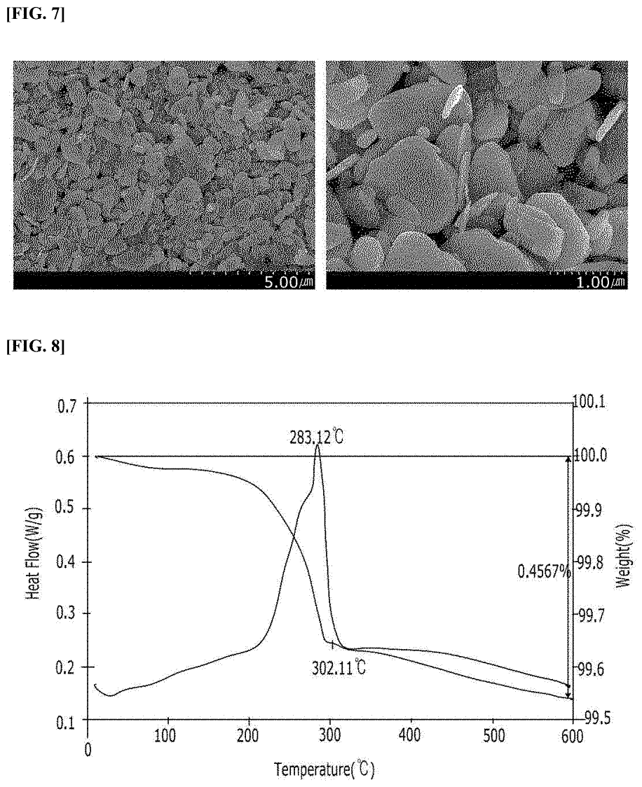

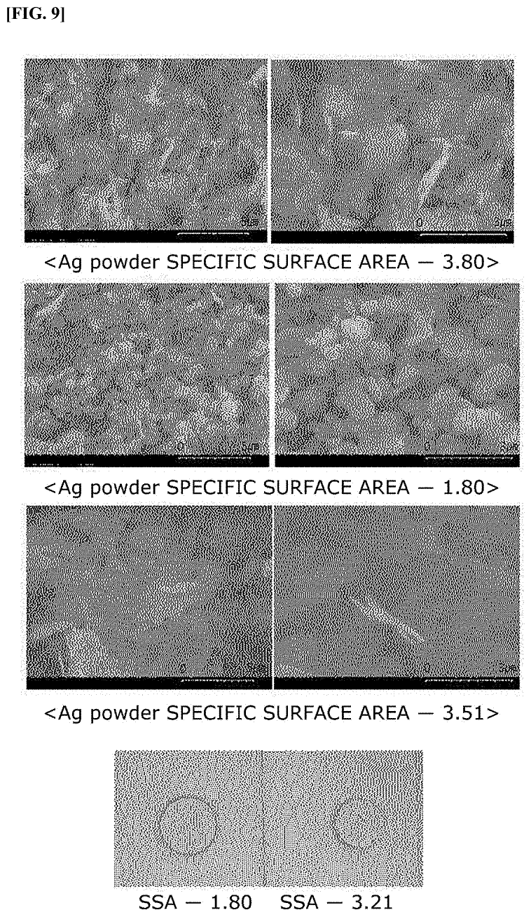

FIG. 7 is a SEM photograph showing a grain shape of the Ag powder subjected to the bead milling process according to the Example of the present disclosure.

As shown in FIG. 7, the Ag powder subjected to the bead milling process is manufactured in the intermediate grain shape between the spherical nanoparticle shape and the flake form. The grain shape of the Ag powder has a length of a long axis in the range of 0.80 μm to 1.3 μm and a thickness in the range of 40 nm to 80 nm.

FIG. 8 is a graph showing the result of the heat analysis of the Ag powder of FIG. 7.

As shown in FIG. 8, as a result of the heat analysis of the Ag powder subjected to the bead milling process, the Ag powder is implemented as particles having a clean surface, a total content of the organic material is 0.5% or less, and a total content of the organic material after pressure sintering is about 0.1%.

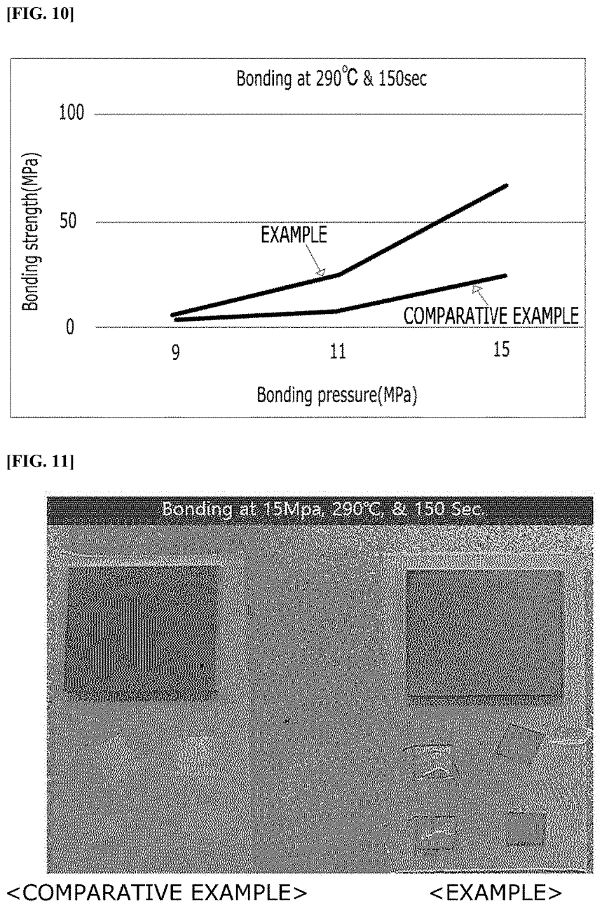

FIG. 9 is a SEM photograph showing an example in which a specific surface area, grain shape, and shrinkage rate of the Ag powder were controlled through the classification and bead milling processes.

As shown in FIG. 9, it can be confirmed that the specific surface area, the grain shape, and the shrinkage rate may be controlled through the classification and bead milling processes. It was confirmed that the Ag powder having a specific surface area (SSA) of 1.3 to 1.8 m²/g had the intermediate grain shape between the spherical nanoparticle shape and the flake form, and the shrinkage rate of the Ag powder having a small specific surface area was smaller than that of the Ag powder having a relatively greater specific surface area.

The Ag paste composition described above may be manufactured to be the bonding film.

The method of manufacturing the Ag paste composition to be the bonding film includes an operation of preparing the base film, an operation of forming the sticky layer on the base film, and an operation of forming the bonding layer by coating the Ag paste composition on the sticky layer by the printing or application method.

Table 1 below shows the physical properties of the Ag paste composition according to the embodiment of the present disclosure.

TABLE 1

| | | Physical properties | |
|---|---|---|---|
| | | of Ag powder of Ag | |
| Items | | paste composition | Remark |
| BET(m²/g) | | 1.3~1.8 | About 325~420 μm |
| | | | when converted to |
| | | | spherical particle |
| Particle | Long axis- | 0.80~1.30 μm | |
| diameter | length | | |
| D50 (μm) | Short axis- | 0.04~0.08 μm | 7~14 when converted |
| | thickness | | to surface area |

| | | |
|---|---|---|
| C content (ppm) | 1500~2000 | 0.01~0.2% of |
| | | organic material |
| 0 content | 200~400 | |
| Density (g/cc) | 10.2 or more | |

According to Table 1, the Ag paste composition has a specific surface area (BET) of the Ag powder of 1.3 to 1.8 m²/g, a length of a long axis of 0.8 μm to 1.3 μm, and a thickness of a short axis of 0.04 μm to 0.08 μm. The thickness of the short axis of the Ag powder is 7 to 14 when converted to the surface area. The Ag paste composition has a C content (ppm) of 1500 to 2000 (0.01 to 0.2% of the organic material), an O content of 200 to 400, and a density (g/cc) of 10.2 or more.

The Ag paste composition described above has a high density and a low content of the organic material in spite of a low specific surface area. In addition, it is also possible to realize the property of the nanoparticle that the thickness of the particle diameter is about 0.04 μm to 0.08 μm (40 nm to 80 nm). The specific surface area of the spherical nanoparticle of 100 nm class is about 5.5 to 6.0 m²/g, which is about 3 to 4 times the specific surface area of 1.3 to 1.8 m²/g of the Ag paste composition according to the present disclosure.

FIG. 10 is a graph comparing the bonding strength of the Ag paste composition according to the Example of the present disclosure with that of a competitor's product (Comparative Example).

As shown in FIG. 10, in the Example, it is possible to secure a sufficient bonding strength even under a short sintering condition at 290° C., and the bonding strength was very highly formed to be 65 MPa under the pressing condition of 15 MPa.

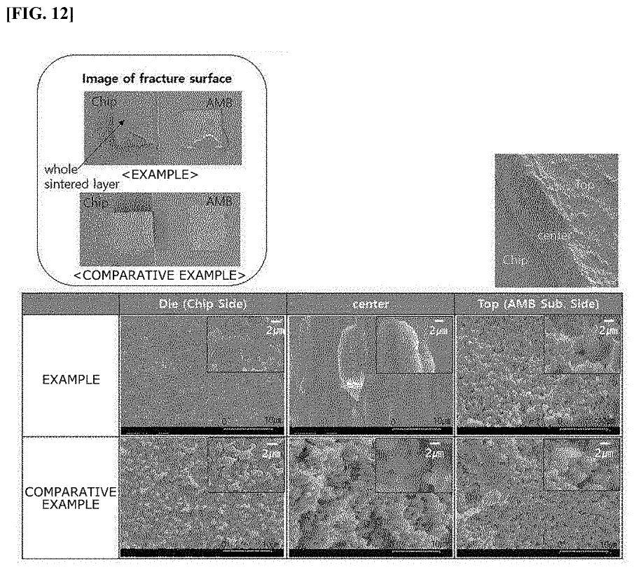

FIG. 11 is a photograph of broken surfaces of the Example and Comparative Example in FIG. 10.

As shown in FIG. 11, in the Example, a portion of the Ag bonding layer was separated, while in the Comparative Example, the bonded surface between the bonding layer and the substrate was broken. In the Example, the Ag bonding layer has the intermediate grain shape between the spherical nanoparticle shape and the flake form. In the Comparative Example, the Ag bonding layer was formed of the spherical nanoparticle.

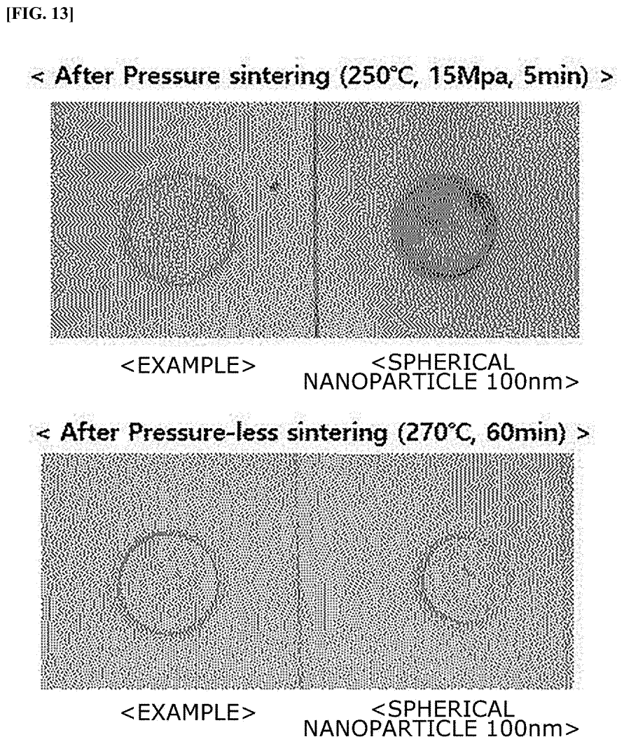

FIG. 12 is a photograph comparing shrinkage rates, the occurrence of bending, and micro-structures of a bonding layer of the Example of the present disclosure and a bonding layer of the Comparative Example (competitor's product).

As shown in FIG. 12, when comparing shapes of the broken surfaces in the SEM photographs after measuring the bonding strength, the Ag bonding layer was ruptured in the middle, and in the Comparative Example (competitor's product), the entire bonding layer was separated from the substrate. This phenomenon was confirmed in the Example that the Ag bonding layer was relatively well sintered and thus the strength of the bonding layer was increased. This is confirmed because the particle of the Ag powder has the intermediate grain shape between the spherical nanoparticle shape and the flake form. In Comparative Example, the particle of the Ag powder is close to a spherical shape.

Furthermore, in the Example, the Ag bonding layer was ruptured at about 65 MPa, and in the Comparative Example, the Ag bonding layer was ruptured at about 23 MPa.

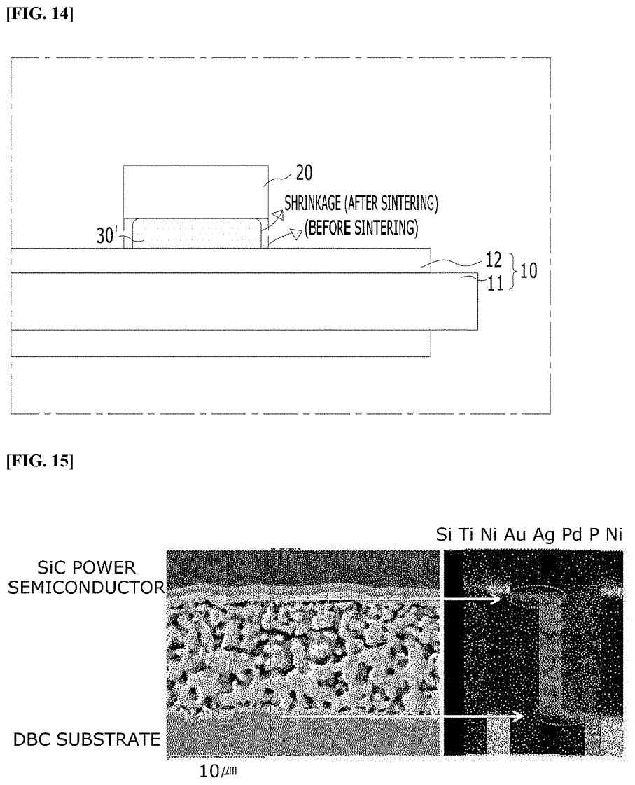

Table 2 below shows the shrinkage rate after pressure sintering and pressure-less sintering in the Example and the Comparative Example. FIG. 13 is a photograph comparing the shrinkage rates of the Example of the present disclosure and the Comparative Example.

TABLE 2

| | | | | Comparative Example | |
|---|---|---|---|---|---|
| | | Example | | Spherical nanoparticle | |
| Items | | Ag paste composition | | 100 nm | |
| Sintering | Pressure (Mpa) | 15 | Pressure-less | 15 | Pressure-less |
| condition | Temperature | 250/5 | 270/60 | 250/5 | 270/60 |
| | (° C.)/Time | | | | |
| After | Thickness | 43.8 | 11.48 | 62.5 | 20.54 |
| sintering | Width | 0.64 | 5.68 | 4.71 | 23.83 |
| Shrinkage | | | | | |
| rate (%) | | | | | |

Table 2 and FIG. 13 show that there is a large difference in shrinkage rates in the pressure sintering and the pressure-less sintering, and a difference between a shrinkage rate of about 20% upon pressure-less sintering and a shrinkage rate of about 5% upon pressure sintering. This has a great advantage in generating residual stress upon sintering.

Therefore, it can be seen that the Ag paste composition in the Example of the present disclosure may have about 20% smaller shrinkage rate than the Comparative Example, have relatively few defects due to jig tolerance after sintering, and prevent cracks in the bonding layer in the sintering process, thereby contributing to reducing defects.

FIG. 14 is a view for describing a state of being shrunk after sintering a bonding layer bonding an object to a substrate according to the Example of the present disclosure.

As shown in FIG. 14, the sintered bonding layer 30′ has a shrinkage rate, but the shrinkage rate is as small as about 6%. Furthermore, the sintered bonding layer 30′ does not vertically shrink well, and small shrinkage occurs on both sides thereof, which is because the Ag powder forming the bonding layer 30′ has the intermediate grain shape between the spherical nanoparticle shape and the flake form. The intermediate grain shape between the spherical nanoparticle shape and the flake form increases a coupling force of the sintered bonding layer 30′, thereby improving a breakage strength.

Table 3 below shows the bonding temperatures in the Example and the Comparative Example.

TABLE 3

| | Initiating | | |
|---|---|---|---|
| | temperature | | |
| | (° C.) at | End of weight | Ag reaction |
| | which organic | reduction | temperature |
| Items | binder is burned | (° C.) | (° C.) |
| Example | 160 | 313 | 307 |
| Comparative | 165 | 315 | 319 |
| Example | | | |

According to Table 3, in the Example and the Comparative Example, the sintering bonding is possible at about 250° C. In addition, since there is no gas causing cracks due to the minimization of the organic material when the temperature rises to 350° C. to 400° C. due to the occurrence of an overvoltage, it is possible to prevent cracks in the bonding layer. In addition, in the Example, since 90 wt % or more of the Ag powder is maintained, it is possible to have the high heat conductivity, thereby improving the heat dissipation characteristics.

Table 4 below shows the result of measuring the heat conductivities (W/mk) in the Example and the Comparative Example.

TABLE 4

| | | | Pressure sintering | | |
|---|---|---|---|---|---|
| | Pressure-less sintering | | 240° C./ | 250° C./ | 250° C./ |
| Sintering | 270° C./ | 270° C./ | 5 min/ | 5 min/ | 5 min/ |
| condition | 30 min | 60 min | 15 MPa | 10 MPa | 15 MPa |
| Example | 152.92 | 151.01 | 265.82 | 236.20 | 288.08 |
| (Ag paste | | | | | |
| composition) | | | | | |
| Comparative | 76.80 | 109.19 | — | — | 280.96 |
| Example | | | | | |
| (Spherical | | | | | |
| nanoparticle | | | | | |
| 100 nm) | | | | | |

According to Table 4, the heat conductivity in the Example is relatively higher than the heat conductivity in the Comparative Example to which the spherical nanoparticle is applied. Upon pressure-less sintering, it is shown in the Example that the heat conductivity is about 150 W/mk, and it is shown in the Comparative Example that the heat conductivity is 70 to 100 W/mk.

Upon pressure sintering, the Example shows that the heat conductivity is 280 W/mk or more and is greater than or equal to that of a case where the spherical nanoparticle is applied. From the above experimental results, it can be seen that the heat conductivity may be increased by controlling the surface area and particle shape of the Ag particle. In addition, it can be seen that the pressure sintering increases the heat conductivity by minimizing pores.

FIG. 15 is a photograph of a structure of a sintered bonding layer after arranging the Ag paste composition between a power semiconductor chip and a direct bonded copper (DBC) substrate and pressure-less sintering the same.

As shown in FIG. 15, as a result of analyzing components using an energy dispersive X-ray spectroscopy (EDX) by performing the pressure-less sintering at 250° C. for 30 minutes, it can be confirmed that Au in the semiconductor chip and ions in the sintered bonding layer are well exchanged, and there is no exchange problem between Pd in the DBC substrate and the ions in the Ag-sintered bonding layer.

Therefore, it can be seen that even when the Ag powder formed of nanoparticle is not used, by using the high-density Ag paste composition to which the Ag particle having the clean surface is applied, it is possible to sufficiently exchange the ions in the bonding layer, thereby realizing the bonding strength.

As described above, according to the present disclosure, since the high specific surface area is not used, it is possible to reduce volatilization in mass production and prevent process defects due to shrinkage upon bonding sintering, thereby improving workability.

In addition, according to the present disclosure, since the Ag powder having the clean surface is used, sintering is possible at about 250° C. even without nanoparticle.

In addition, according to the present disclosure, by sintering the nanoparticle in advance before performing the pressing by a press that occurs when the nanoparticles are used, it is possible to reduce defects reducing the bonding strength, thereby securing reliability.

In addition, according to the present disclosure, it is possible to manufacture the Ag paste composition to be the film-shaped product.

As described above, according to the present disclosure, it is possible to stably bond the semiconductor chip to the substrate instead of the reflow method and the soldering method.

The best embodiments of the present disclosure have been disclosed in the drawings and the specification. Here, although specific terms have been used, these are only used for the purpose of describing the present disclosure and are not used to restrict the meaning thereof or limit the scope of the present disclosure described in claims. Therefore, those skilled in the art will understand that various modifications and equivalent other embodiments are possible from the present disclosure. Therefore, the true technical scope of the present disclosure should be determined by the technical spirit of the appended claims.

1. An Ag paste composition forming a sintered bonding layer between a first object and a second object by being coated on the first object and pressure-sintering the first object toward the second object, comprising:
90 to 99 wt % of Ag powder; and
1 to 10 wt % of an organic binder.

2. The Ag paste composition of claim 1, wherein the Ag powder has an intermediate grain shape between a spherical nanoparticle shape and a flake form.

3. The Ag paste composition of claim 1, wherein the Ag powder has a specific surface area (Brunauer, Emmett, Teller (BET)) in the range of 1.3 to 1.8 m²/g.

4. The Ag paste composition of claim 1, wherein the grain shape of the Ag powder has a length of a long axis in the range of 0.80 μm to 1.3 μm and a thickness in the range of 0.04 μm to 0.08 μm.

5. The Ag paste composition of claim 1, which has a total content of an organic material is 2 wt % or less, and
a total content of the organic material of 0.1 wt % or less after pressure sintering.

6. The Ag paste composition of claim 1, which has a sintering temperature in the range of 200° C. to 300° C. upon pressure sintering.

7. A bonding film comprising:
a base film;
a sticky layer formed on the base film; and
a bonding layer formed on the sticky layer and made of the Ag paste composition.

8. The bonding film of claim 7, wherein the base film is formed as one of a polyethylene (PET) film, a polyimide (PI) film, and a polyurethane (PU) film.

9. The bonding film of claim 7, wherein the sticky layer is formed as an optical clear adhesive (OCA) or an optical clear resin (OCR).

10. The bonding film of claim 7, wherein the Ag paste composition includes:
90 to 99 wt % of Ag powder; and
1 to 10 wt % of an organic binder.

11. The bonding film of claim 10, wherein the Ag powder has an intermediate grain shape between a spherical nanoparticle shape and a flake form.

12. The bonding film of claim 10, wherein the Ag powder has a specific surface area (BET) in the range of 1.3 to 1.8 m²/g.

13. The bonding film of claim 10, wherein the grain shape of the Ag powder has a length of a long axis in the range of 0.80 μm to 1.3 μm and a thickness in the range of 40 nm to 80 nm.

14. The bonding film of claim 10, wherein the Ag paste composition has a total content of an organic material is 2 wt % or less, and
a total content of the organic material of 0.1 wt % or less after pressure sintering.

15. The bonding film of claim 10, wherein a sintered bonding layer is formed between a first object and a second object by transferring the bonding layer to the first object and pressure-sintering the first object toward the second object, and
a sintering temperature upon pressure sintering is in the range of 200° C. to 300° C.
